(19) United States
(12) Patent Application Publication
(10) Pub. No.: US 2008/0308900 A1
(43) Pub. Date: Dec. 18, 2008

(54) ELECTRICAL FUSE WITH SUBLITHOGRAPHIC DIMENSION

(75) Inventors: Deok-kee Kim, Bedford Hills, NY (US); Wai-Kin Li, Beacon, NY (US); Haining S. Yang, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/761,403

(22) Filed: Jun. 12, 2007

(51) Int. Cl. H01L 29/00; G03F 1/00

(52) U.S. Cl. 257/529; 430/5; 257/E29.001

(57) ABSTRACT

A photolithography mask contains at least one sublithographic assist feature (SLAF) such that the image of the fuselink shape on a photoresist contains a constructive interference portion and two neck portions. The width of the constructive interference portion is substantially the same as a critical dimension of the lithography tool and the widths of the two neck portions are sublithographic dimensions. The image on a photoresist is subsequently transferred into an underlying semiconductor layer to form an electrical fuse. The fuselink contains a constructive interference portion having a first width which is substantially the same as the critical dimension of the lithography tool and two neck portions having sublithographic widths. The inventive electrical fuse may be programmed with less voltage bias, current, and energy compared to prior art electrical fuses.

### FIELD OF THE INVENTION

The present invention relates to semiconductor memory devices, and particularly to electrical fuse structures with sublithographic dimensions and photolithographic masks having a pattern for forming the same.

### BACKGROUND OF THE INVENTION

Electrical fuses (eFuses) are used in the semiconductor industry to implement array redundancy, field programmable arrays, analog component trimming circuits, and chip identification circuits. Once programmed, the programmed state of an electrical fuse does not revert to the original state on its own, that is, the programmed state of the fuse is not reversible. For this reason, electrical fuses are called One-Time-Programmable (OTP) memory elements.

Electrical fuses offer several advantages over conventional laser fuses including compact design, scalability of size, reduced collateral damage to surrounding structures during programming, and field programmability. The mechanism for programming an electrical fuse is electromigration of a metal semiconductor alloy induced by an applied electrical field and a raised temperature on a portion of the electrical fuse structure. The metal semiconductor alloy is electromigrated under these conditions from the portion of the electrical fuse structure, thereby increasing the resistance of the electrical fuse structure.

An intact electrical fuse is in a low initial resistance state that may be changed to a higher resistance state through programming, i.e., through electrical bias conditions applied to the fuse. Typically, the metal semiconductor alloy is a metal silicide formed on a polysilicon gate conductor. The resistance of the electrical fuse structure is sensed by sense circuitry to determine whether the electrical fuse is programmed. The state of the electrical fuse, i.e., whether the electrical fuses is programmed or not, constitutes one bit of information stored in an electrical fuse array.

The rate and extent of electromigration during programming of an electrical fuse is dependent on the temperature and the electrical field at the electromigrated portion. Typically, the electromigrated portion of the electrical fuse comprises a narrow strip, or a “fuselink,” of a stack of semiconductor material and metal semiconductor alloy.

Referring to FIGS. 1A and 1B, a prior art electrical fuse is shown. FIG. 1A is a top-down view of the prior art electrical fuse and FIG. 1B is a vertical cross-sectional view of the prior art electrical fuse in the plane B-B′ in FIG. 1A. The prior art electrical fuse comprises an anode 30, a fuselink 40, and a cathode 50, and is formed on shallow trench isolation 20 located in a semiconductor substrate 10. The anode 30 comprises an anode semiconductor 32 and an anode metal-semiconductor alloy 34. The fuselink 40 comprises a fuselink semiconductor 42 and a fuselink metal-semiconductor alloy 44. The cathode 50 comprises a cathode semiconductor 52 and a cathode metal-semiconductor alloy 54. A gate spacer 55 surrounds the prior art electrical fuse. The anode semiconductor 32, the fuselink semiconductor 42, and the cathode semiconductor 52 comprise a semiconductor material, for example polysilicon. The metal-semiconductor alloys (32, 42, 52) may be formed by metallization of the semiconductor material underneath. If the underlying semiconductor material is polysilicon, the metal-semiconductor alloys are a silicide.

The prior art electrical fuse is programmed by applying a voltage bias between the anode 30 and the cathode 50 to cause a current to flow from the anode 30 to the cathode 50. As the current passes through the fuselink 40, electromigration is induced within the fuselink 40. The current density as well as the temperature of the electromigrated region in the fuselink 40 determines the effectiveness of electromigration. In general, high temperature and high current density in the fuselink 40 are conducive to electromigration. By reducing the width of the electromigrated region in the fuselink 40, the current density and the temperature increases in the electromigrated region during programming of the electrical fuse.

Typically, however, the width of fuselink 40 is limited by lithographic limitations. For each generation of lithographic tools with a given set of light source wavelength and numerical aperture (NA), a “critical dimension” is defined as the dimension of smallest geometrical features which can be formed during semiconductor manufacturing. More specifically, the width of the narrowest patterned line or the smallest distance between two lines that may be printed on a photoresist on a semiconductor substrate is referred to by the critical dimension for a given lithography tool. The critical dimension depends on the choice of lithographic tools and is typically the minimum feature size that is printed with the lithographic tool.

The width of the fuselink 40 in the prior art electrical fuse shown in FIG. 1 is limited by the critical dimension of the lithography tool used for patterning the fuselink 40. In each generation of lithographic tools, therefore, reduction of the width of a portion of the fuselink 40 below the critical dimension of the lithography tool employed to pattern the fuselink requires lithographic techniques that generate a sublithographic dimension in the fuselink 40.

U.S. Pat. No. 6,271,574 to Delpech et al. provides one exemplary prior art structure that forms a fuselink with a sublithographic width within the fuselink, wherein dummy elements are formed next to a thinned portion of the fuselink having the sublithographic width. U.S. Patent Application Publication No. 2004/0004268 to Brown et al. provides another exemplary structure with a sublithographic width within the fuselink by forming a break or an offset jog in line features on a photolithography mask.

While providing a sublithographic width within a fuselink, the exemplary prior art structures do not provide a mechanism to limit heat transfer to a cathode or to an anode to maintain high temperature within the fuselink. Further, the prior art structure disclosed by Delpech et al. requires printing of dummy structures around the fuselink, which occupies a substantial semiconductor area. Also, the prior art structure according to Brown et al. provides a sublithographic fuselink width that is highly sensitive to the physical pattern on the mask.

Therefore, there exists a need for an electrical fuse that has a sublithographic width in the electromigrated region and provides high degree of heat containment to facilitate electromigration at a low current and low voltage bias across the anode and the cathode of the fuse.

Further, there exists a need for an electrical fuse with high stability in the dimension of the sublithographic width against microscopic defects in the pattern on a photolithography mask.

In addition, there exists a need for an electrical fuse with the advantage described above, which has a compact design so that minimal semiconductor area is utilized to form the electrical fuse.

### SUMMARY OF THE INVENTION

The present invention addresses the needs described above by providing an electrical fuse structure with two sublithographic necks within a fuselink by employing at least one sublithographic assist feature (SLAF) in a photolithography mask. A sublithographic assist feature is a pattern on a photolithography mask having at least one sublithographic dimension such that its own image is not printed on a photoresist during exposure but it affects the image of other printed features on the photolithography mask.

According to the present invention, a photolithography mask contains a fuse portion having an anode shape, a cathode shape, and a fuselink shape. In addition, at least one sublithographic assist feature (SLAF) is formed within the photolithography mask such that the image of the fuselink shape on the photoresist contains a “constructive interference portion,” in which constructive interference occurs between the component of monochromatic light through the fuselink shape and the component through at least one SLAF in a lithography tool. The image of the fuselink shape also contains two neck portions which do not have constructive interference of the fuselink shape and the at least one SLAF, and adjoins the constructive interference portion. The width of the constructive interference portion is substantially the same as a critical dimension of the lithography tool and the widths of the two neck portions are sublithographic dimensions, i.e., less than the critical dimension.

The image on a photoresist is subsequently transferred into an underlying semiconductor layer, which may be a polysilicon layer, for example, forming an electrical fuse with substantially the same shape as the image on the photoresist. Thus, the patterned semiconductor layer forms an electrical fuse comprising an anode, a cathode, and a fuselink. The fuselink contains a constructive interference portion having a first width which is substantially the same as the critical dimension of the lithography tool and two neck portions having sublithographic widths. During programming of the electrical fuse, a voltage bias is applied across the anode and the cathode. The two neck portions provide increased current density as well as heat containment within the fuselink. Thus, the inventive electrical fuse may be programmed with less voltage bias, current, and energy compared to prior art electrical fuses. Also, since no SLAF structures are printed on the photoresist, the inventive electrical fuse does not require any dummy structure adjacent to the fuselink.

According to one aspect of the present invention, an electrical fuse is provided, which comprises:

an anode located on a semiconductor substrate;

a cathode located on the semiconductor substrate and disjoined from the anode; and

a fuselink located on the semiconductor substrate and abutting the anode and the cathode, wherein the fuselink contains a constructive interference portion having a first width, a first neck portion abutting the constructive interference portion and having a second width, and a second neck portion abutting the constructive interface portion, disjoined from the first neck portion, and having a third width, wherein the first width is substantially a critical dimension of a lithography tool, and the second and third widths are sublithographic dimensions of the lithography tool.

Preferably, the first width is obtained by a constructive interference of a fuselink shape, or a shape on a photolithography mask corresponding to the fuselink, and at least one sublithographic assist feature on a photolithography mask. The at least one sublithographic feature may be rectangular in shape.

In one embodiment, the first neck may abut the anode and the second neck may abut the cathode.

In another embodiment, the fuselink may further comprise:

an anode adjoining portion having a fourth width and abutting the anode and the first neck; and

a cathode adjoining portion having a fifth width and abutting the cathode and the second neck.

Preferably, no physical shape other than the anode and cathode is present at the same level as the fuselink within the distance of two times the critical dimension from the fuselink. More preferably, no physical shape other than the anode and cathode is present at the same level as the fuselink within the distance of four times the critical dimension from the fuselink. The la of shapes in the vicinity of the fuselink enables effective utilization of area such that other circuit elements may be placed adjacent to the area in which no other physical shapes are present.

According to another aspect of the present invention, a photolithography mask having a pattern of at least one opaque portion and at least one transparent portion is provided. The pattern comprises:

an anode shape;

a cathode shape disjoined from the anode shape;

a fuselink shape having a pair of two substantially parallel edges and abutting the anode shape and the cathode shape; and

at least one sublithographic assist feature not adjoining the fuselink shape, wherein an image of the photolithography mask contains a constructive interference portion having a first width, a first neck portion abutting the constructive interference portion and having a second width, and a second neck portion abutting the constructive interface portion, disjoined from the first neck portion, and having a third width, and the first width is substantially a critical dimension of a lithography tool, and the second and third widths are sublithographic dimensions of the lithography tool.

Preferably, the at least one sublithographic assist feature has at least one side that is parallel to and shorter than the pair of two substantially parallel edges. The at least one sublithographic feature may be rectangular in shape.

The fuselink shape may further comprise:

an anode adjoining shape having another pair of substantially parallel edges; and

a cathode adjoining shape having yet another pair of substantially parallel edges.

The another pair of substantially parallel edges and the pair of the yet another pair of substantially parallel edges are parallel to each other and offset by a distance greater than the critical dimension. The pair of two substantially parallel edges may be at an angle to the another pair of substantially parallel edges, wherein the angle is in the range from 0 degree to 180 degrees. The angle may be substantially 90 degrees.

The inventive electrical fuse structures provide two neck portions (the first neck portion and the second neck portion) that adjoin the constructive interference portion to limit heat transfer to the cathode and to the anode. Due to the reduction in the heat transfer, a high temperature is maintained within the fuselink, and especially within the constructive interference portion, during programming. Further, the sublithographic third width of the second neck portion on the cathode side increases the current density within the second neck portion, which is a portion of an electromigration region. The combination of the increased current density and the high temperature facilitates electromigration of a metal-semiconductor alloy at a low current and voltage bias across the anode and the cathode. No printing of dummy structures around the fuselink is needed, which makes the inventive electrical fuse structure conducive to a compact design. Also, the sublithographic widths of the two neck portions are less sensitive to defects in the physical pattern on a photolithographic mask.

### BRIEF DESCRIPTION OF THE DRAWINGS

FIG. 1A is a top-down view of an exemplary prior art electrical fuse.

FIG. 1B is a vertical cross-sectional view of the exemplary prior art electrical fuse in FIG. 1A in the plane B-B′.

FIGS. 2-4 show sequential cross-sectional views of an exemplary electrical fuse at various stages of a manufacturing process according to the present invention.

FIGS. 5A, 6A, 7A, and 8A show photolithographic masks according to a first, second, third, and fourth embodiment of the present invention, respectively.

FIGS. 5B, 6B, 7B, and 8B show electrical fuses according to the first, second, third, and fourth embodiment of the present invention, respectively.

FIG. 9 shows the result of a simulation in which a fuselink shape and sublithographic assist features are superposed with the image of a fuselink on a photoresist according to the present invention.

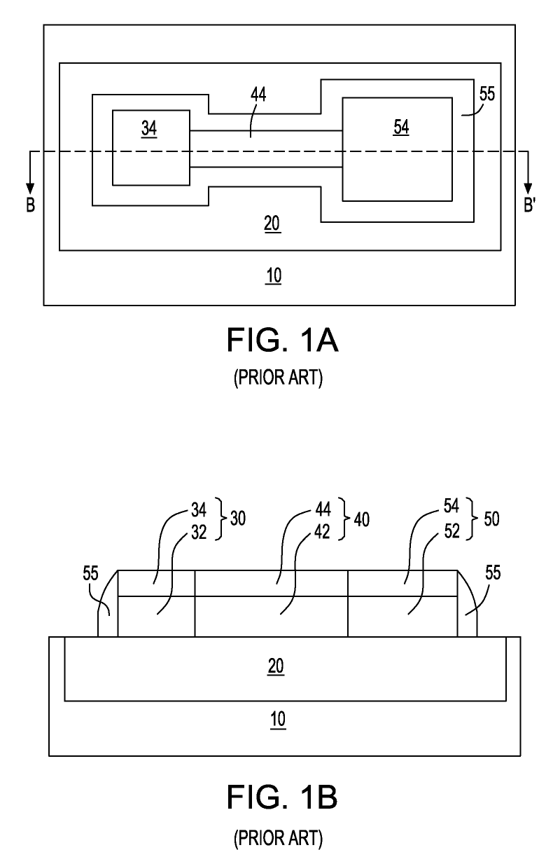

### DETAILED DESCRIPTION OF THE INVENTION

As stated above, the present invention relates to electrical fuse structures with sublithographic dimensions and photolithographic masks having a pattern for forming the electrical fuse structures. These aspects of the present invention are now described in detail with accompanying figures. It is noted that like and corresponding elements are referred to by like reference numerals.

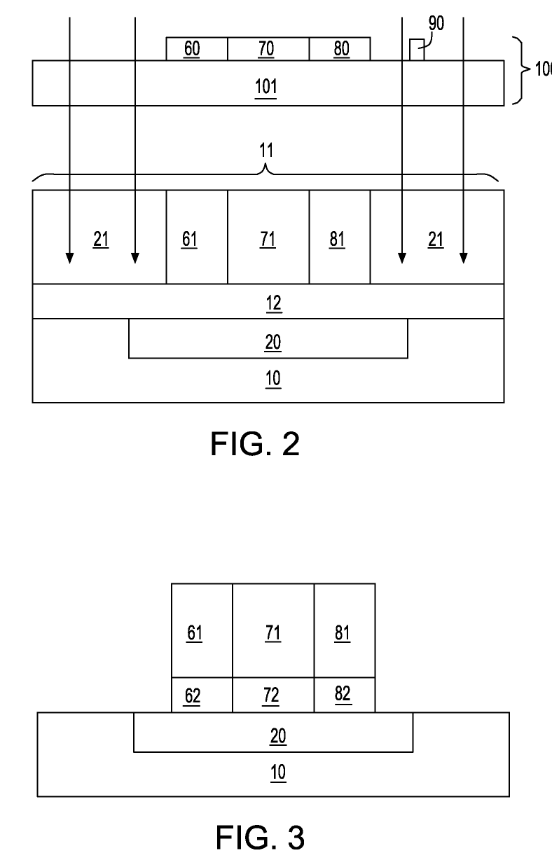

Referring to FIG. 2, a vertical cross-sectional view of a photolithographic mask 100 and a semiconductor structure is shown during an exposure step of a manufacturing process that may be employed to practice the present invention. A semiconductor material layer 12 is formed on a semiconductor substrate 10. Preferably, the semiconductor material layer 12 is also formed on the shallow trench isolation 20. A photoresist 11 is applied to the top surface of the semiconductor layer 12. The photolithographic mask 100, comprising a transparent plate 101 on which an opaque film containing a pattern for an electrical fuse is located, is employed in a lithography tool to form an image of an electrical fuse. The pattern contains an anode shape 60, a fuselink shape 70, and a cathode shape 80. Further, the pattern contains at least one sublithographic assist feature 90, which does not form an image of its own on the photoresist but modifies the image of a small shape located in proximity on the photolithographic mask 100. The opaque portion of the photolithographic mask 100 may comprise the anode shape 60, the fuselink shape 70, and the cathode shape 80. Alternatively, the opaque portion of the photolithographic mask 100 may comprise the complement of the anode shape 60, the fuselink shape 70, and the cathode shape 80, i.e., the background may be opaque while the area of the anode shape 60, the fuselink shape 70, and the cathode shape 80 is transparent.

The photoresist 11 may be a positive photoresist or a negative photoresist, i.e., may be hardened by exposure or by a lack of exposure. The photoresist 11 is exposed in a lithography tool by a monochromatic light beam (symbolized by arrows in FIG. 2) that passes through the photolithographic mask 100. It is understood that FIG. 2 is a schematic drawing illustrating the exposure process, that other components of the lithography tool, such as lenses, are typically present in the path of the monochromatic beam, and that the beam is not necessarily perpendicular to the substrate 10. After exposure of the photoresist 11 in a lithography tool, the hardened portion of the photoresist 11 forms a pattern for an anode image 61, a fuselink image 71, and a cathode image 81. The unhardened portion of the photoresist 21 is removed after developing.

Referring to FIG. 3, the pattern in the hardened portion of the photoresist 11 is transferred into the semiconductor material layer 12 by a reactive ion etch or any other dry etching process. The remaining portion of the semiconductor material layer 12 comprises an anode semiconductor 62, a fuselink semiconductor 72, and a cathode semiconductor 82. The patterns for the fuselink image 71 and the fuselink semiconductor 72 are substantially identical as seen in top-down views. Any differences in the dimensions of the two patterns are caused only by etch bias, which is typically less than 10 nm. Similar geometrical relationships apply between the anode image 61 and the anode semiconductor 62, and between the cathode image 81 and the cathode semiconductor 82.

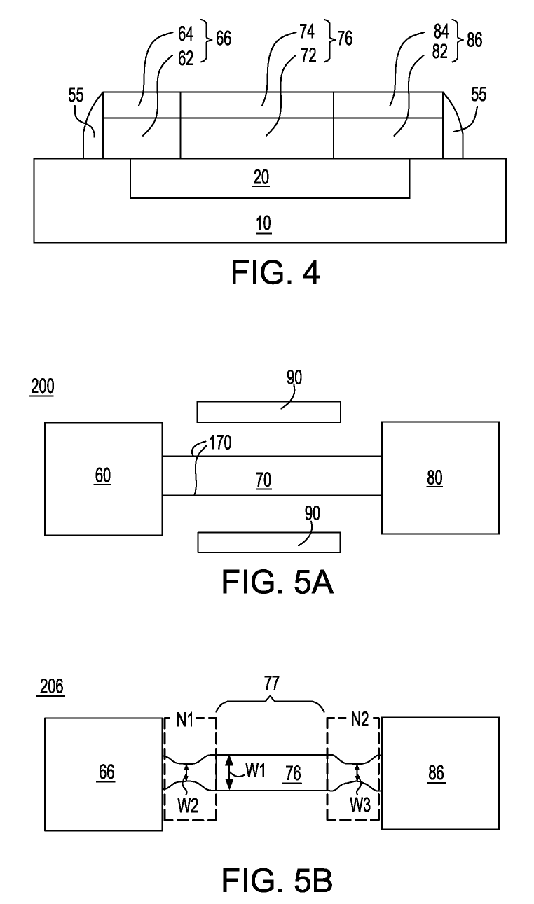

Referring to FIG. 4, the unhardened portion of the photoresist 21 is removed. After forming a gate spacer 55 and metal-semiconductor alloys, an electrical fuse is formed. Specifically, an anode metal-semiconductor alloy 64 is formed directly on the anode semiconductor 62. A fuselink metal-semiconductor alloy 74 is formed directly on the fuselink semiconductor 72. A cathode metal-semiconductor alloy 84 is formed directly on the cathode semiconductor 82. The electrical fuse comprises an anode 66, a fuselink 76, and a cathode 86. The anode 66 comprises the anode semiconductor 62 and an anode metal-semiconductor alloy 64. The fuselink 76 comprises the fuselink semiconductor 72 and a fuselink metal-semiconductor alloy 74. The cathode 86 comprises the cathode semiconductor 82 and a cathode metal-semiconductor alloy 84.

The features of the present invention are manifested in the geometry of the at least one SLAF 90 and other similar SLAFs and in the shapes of the electrical fuses obtained therefrom. These features are described below in top-down views of exemplary inventive electrical fuse structures and exemplary inventive photolithographic masks.

Referring to FIG. 5A, a top-down view of a first exemplary photolithographic mask 200 according to a first embodiment of the present invention is shown. The first exemplary photolithographic mask 200 comprises a transparent plate on which an opaque film with a pattern having at least one opaque portion and at least one transparent portion is affixed. The pattern comprises an anode shape 60, a fuselink shape 70, a cathode shape 80, and at least one sublithographic assist feature (SLAF) 90. The physical structure for the pattern for the anode shape 60, the fuselink shape 70, the cathode shape 80, and the at least one SLAF 90 may comprise either a set of transparent areas against an opaque background or a set of opaque areas against a transparent background. The opaque area contains the opaque film. The transparent area does not contain the opaque film.

The fuselink shape 70 abuts both the anode shape 60 and the cathode shape 80. Preferably, the fuselink shape 70 is rectangular and has a pair of two substantially parallel edges 170. The pair of two substantially parallel edges 170 abuts the anode shape 60 and the cathode shape 80. At least one sublithographic assist feature 90 is present on the first exemplary photolithographic mask 200. The at least one sublithographic assist feature 90 does not adjoin the fuselink shape 70. Preferably, the at least one sublithographic assist feature 90 is rectangular. The width of the at least one sublithographic assist feature 90 is sublithographic, i.e., less than a dimension needed to print a physical image on a photoresist. Therefore, the image on the photoresist 11 (shown in FIG. 2) does not contain a direct image of the at least one sublithographic assist feature 90.

The at least one sublithographic assist feature 90 may comprise a pair of sublithographic assist features located on each side of the fuselink shape 70. Preferably, the at least one sublithographic assist feature 90 has at least one side that is parallel to and shorter than the pair of two substantially parallel edges 170. The at least one sublithographic feature 90 may be rectangular in shape. No pattern is present between the at least one sublithographic assist feature 90 and the anode shape 60 and between the at least one sublithographic assist feature 90 and the cathode shape 80 in the first exemplary photolithographic mask 200.

Referring to FIG. 5B, a top-down view of a first exemplary electrical fuse 206 is shown. The first exemplary electrical 206 fuse is manufactured by utilizing the first exemplary photolithographic mask 200 and employing the manufacturing processes described above. The image formed on the photoresist 11 as shown in FIG. 2 is transferred into the semiconductor material layer 12 to form an anode semiconductor 62, a fuselink semiconductor 72, and a cathode semiconductor 82. Through a reactive ion etch and metallization, an anode 66, a fuselink 76, and a cathode are formed as described above. The first exemplary electrical fuse 206 comprises a constructive interference portion 77 having a first width W1, a first neck portion N1 abutting the constructive interference portion 77 and having a second width W2, and a second neck portion N2 abutting the constructive interface portion 77, disjoined from the first neck portion N1, and having a third width W3.

The first width W1 is substantially a critical dimension of a lithography tool, i.e., the width of the narrowest patterned line that may be printed on a photoresist on a semiconductor substrate for the lithography tool used to pattern the photoresist 11. Preferably, the first width W1 is obtained by a constructive interference of the fuselink shape 70 and the at least one sublithographic assist feature 90 on the first exemplary photolithography mask 200. The second width W2 and the third width W3 are sublithographic dimensions of the lithography tool, i.e., smaller than the critical dimension.

The constructive interference portion 77 may have substantially the same width W1 between the first neck portion N1 and the second neck portion N2. The first neck portion N1 abuts the anode 66 and the second neck portion N2 abuts the cathode 86. The areas in the photoresist 11 (shown in FIG. 2) corresponding to the first neck portion N1 and the second neck portion N2 lack a constructive interference between the fuselink shape 70 and the at least one sublithographic assist feature 90, causing the widths of the second width W2 and the third width W3 to be sublithographic.

No physical shape other than the anode 66 and cathode 86 is present at the same level as the fuselink 76 within the distance of two times the critical dimension from the fuselink 76. This contrasts with some prior art structures that require physical dummy structures to be formed adjacent to a fuselink structure. More preferably, no physical shape other than the anode 66 and cathode 86 is present at the same level as the fuselink 76 within the distance of four times the critical dimension from the fuselink. The absence of other physical shapes is due to the use of the at least one sublithographic assist feature (SLAF) 90 which is narrow enough not to form a printable image, i.e., there is no direct image of the at least one SLAF 90. However, the presence or absence of the at least one SLAF 90 determines whether the width of the fuselink 76 is at a critical dimension or at a sublithographic dimension at various locations. The at least one sublithographic assist feature 90 may have a length substantially the same as the length of the constructive interference portion 77.

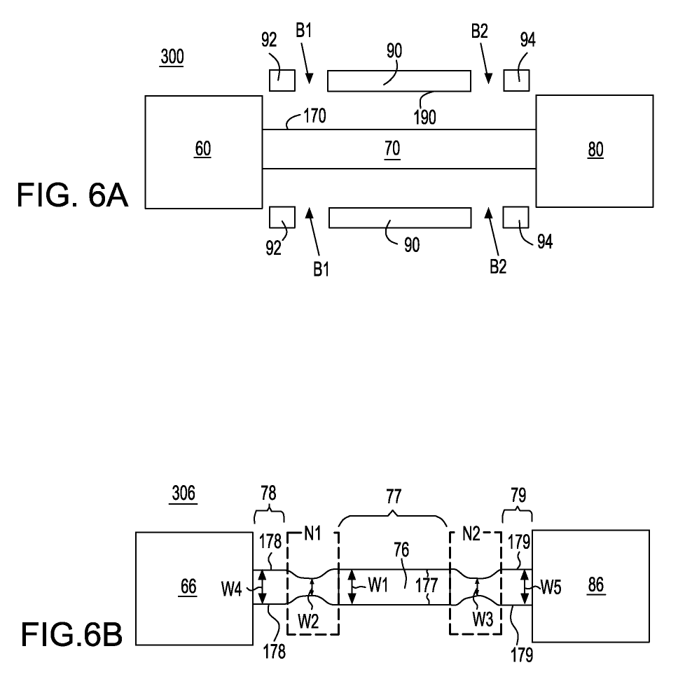

Referring to FIG. 6A, a top-down view of a second exemplary photolithographic mask 300 according to a second embodiment of the present invention is shown. As in the first exemplary photolithographic mask 200, the second exemplary photolithographic mask 300 comprises a transparent plate on which an opaque film with a pattern having at least one opaque portion and at least one transparent portion is affixed. The pattern comprises an anode shape 60, a fuselink shape 70, a cathode shape 80, and at least one sublithographic assist feature (SLAF) 90, which have similar structural characteristics as in the first embodiment.

The at least one sublithographic assist feature 90 may comprise a pair of sublithographic assist features located on each side of the fuselink shape 70. Preferably, the at least one sublithographic assist feature 90 has at least one side 190 that is parallel to and shorter than the pair of two substantially parallel edges 170. The at least one sublithographic feature 90 may be rectangular in shape.

The second exemplary photolithographic mask 300 further comprises at least another sublithographic assist feature 92 located between the at least one sublithographic assist feature 90 and the anode shape 60, and at least yet another sublithographic assist feature 94 located between the at least one sublithographic assist feature 90 and the cathode shape 80. Each of the at least another sublithographic assist feature 92 and at least yet another sublithographic assist feature 94 may comprise a pair of symmetric sublithographic assist features. The pair of two substantially parallel edges 170 abuts the anode shape 60 and the cathode shape 80.

Preferably, the various sublithographic assist features (90, 92, 94) are rectangular and have the same widths. Some of the various sublithographic assist features (90, 92, 94) may be separated by breaks. For example, one of the at least one sublithographic assist feature 90 may be separated from one of the another at least one sublithographic assist feature 92 by a first break B1. Similarly, one of the at least one sublithographic assist feature 90 may be separated from one of the yet another at least one sublithographic assist feature 94 by a second break B2.

Referring to FIG. 6B, a top-down view of a second exemplary electrical fuse 306 is shown. The second exemplary electrical fuse 306 is manufactured by utilizing the second exemplary photolithographic mask 300 and employing the manufacturing processes described above. The second exemplary electrical fuse 306 comprises a constructive interference portion 77 having a first width W1, a first neck portion N1 abutting the constructive interference portion 77 and having a second width W2, and a second neck portion N2 abutting the constructive interface portion 77, disjoined from the first neck portion N1, and having a third width W3. The properties of the first-third widths (W1, W2, W3) are the same as in the first embodiment.

Unlike the first embodiment, however, the first neck portion N1 does not abuts the anode 66. Similarly, the second neck portion N2 does not abut the cathode 86. Instead, the fuselink 76 comprises an anode adjoining portion 78 and a cathode adjoining portion 79. The anode adjoining portion 78 has a fourth width W4 and abuts the anode 66 and the first neck portion N1. The cathode adjoining portion 79 has a fifth width W5 and abuts the cathode 86 and the second neck portion N2.

The second exemplary electrical fuse 306 further comprises a pair of substantially parallel constructive interface portion edges 177 located on the constructive interference portion 77 and separated by the first width W1, a pair of substantially parallel anode adjoining portion edges 178 located on the anode adjoining portion 78 and separated by the fourth width W4, and a pair of substantially parallel cathode adjoining portion edges 179 located on the cathode adjoining portion 79 and separated by the fifth width W5.

Preferably, the fourth width W4 and the fifth width W5 are substantially the same as the first width W1, which is substantially the same as the critical dimension. The pair of the substantially parallel constructive interface portion edges 177 may be substantially coincident with extensions of the pair of the substantially parallel anode adjoining portion edges 178 and the pair of the substantially parallel cathode adjoining portion edges 179.

It is explicitly contemplated herein that the fourth width W4 and/or the fifth width W5 may be different from the first width W1. This is achieved by modifying the rectangular fuselink shape 70 in FIG. 6A to increase the width of the fuselink shape 70 near the anode shape 60 and/or near the cathode shape 80.

As in the first embodiment, no physical shape other than the anode 66 and cathode 86 is present at the same level as the fuselink 76 within the distance of two times the critical dimension from the fuselink 76. More preferably, no physical shape other than the anode 66 and cathode 86 is present at the same level as the fuselink 76 within the distance of four times the critical dimension from the fuselink.

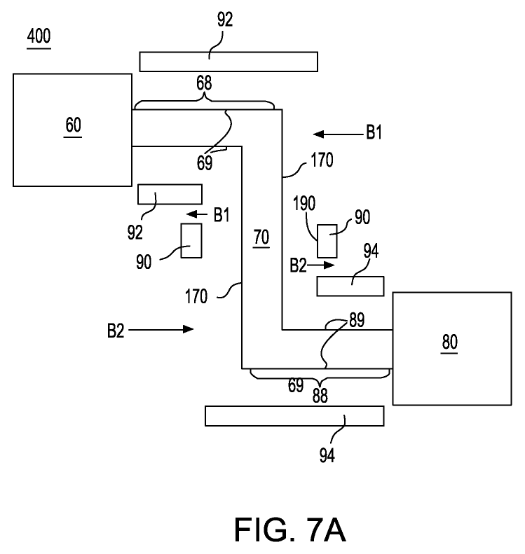

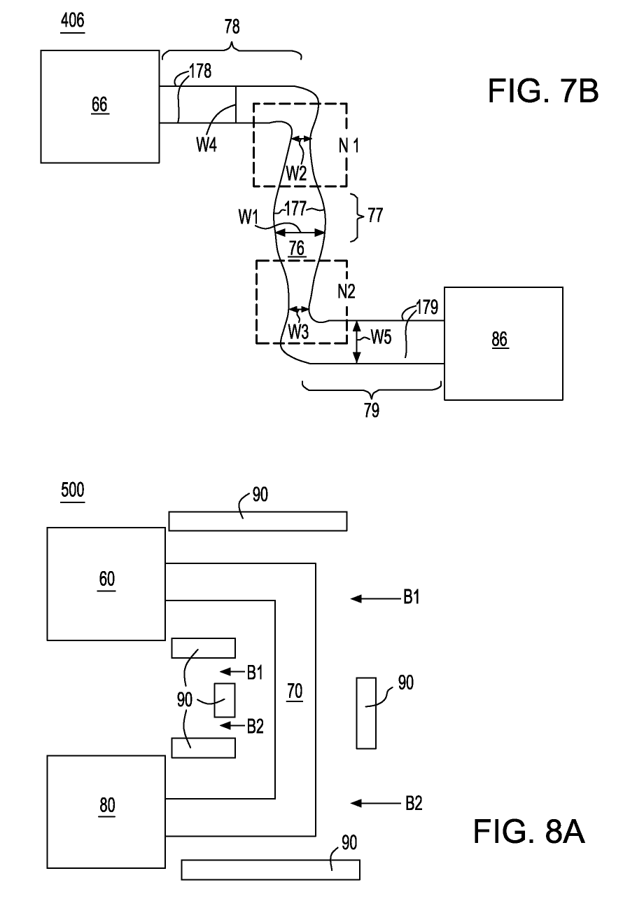

Referring to FIG. 7A, a top-down view of a third exemplary photolithographic mask 300 according to a third embodiment of the present invention is shown. As in the first exemplary photolithographic mask 200, the third exemplary photolithographic mask 400 comprises a transparent plate on which an opaque film with a pattern having at least one opaque portion and at least one transparent portion is affixed. The pattern comprises an anode shape 60, a fuselink shape 70, a cathode shape 80, and at least one sublithographic assist feature (SLAF) 90, which have similar structural characteristics as in the first embodiment.

The at least one sublithographic assist feature 90 may comprise a pair of sublithographic assist features located on each side of the fuselink shape 70. Preferably, the at least one sublithographic assist feature 90 has at least one side 190 that is parallel to and shorter than the pair of two substantially parallel edges 170. The at least one sublithographic feature 90 may be rectangular in shape.

The third exemplary photolithographic mask 400 further comprises at least another sublithographic assist feature 92 located between the at least one sublithographic assist feature 90 and the anode shape 60, and at least yet another sublithographic assist feature 94 located between the at least one sublithographic assist feature 90 and the cathode shape 80. Each of the at least another sublithographic assist feature 92 and at least yet another sublithographic assist feature 94 may comprise a pair of asymmetric sublithographic assist features as shown in FIG. 7A.

Unlike the second exemplary photolithographic mask 300, the pair of two substantially parallel edges 170 does not abut the anode shape 60 or the cathode shape 80. The fuselink shape 70 comprises an anode adjoining shape 68 having another pair of substantially parallel edges 69 and a cathode adjoining shape 88 having yet another pair of substantially parallel edges 89. The another pair of substantially parallel edges 69 and the pair of the yet another pair of substantially parallel edges 89 are parallel to each other and offset by a distance greater than the critical dimension. The pair of two substantially parallel edges 170 may be at an angle to the another pair of substantially parallel edges 69, wherein the angle is in the range from 0 degree to 180 degrees. The angle may be substantially 90 degrees.

The anode shape 60 and the cathode shape 80 are on opposite sides of an imaginary line drawn in the middle of and parallel to the pair of two substantially parallel edges 170.

Referring to FIG. 7B, a top-down view of a third exemplary electrical fuse 406 is shown. The third exemplary electrical fuse 406 is manufactured by utilizing the third exemplary photolithographic mask 400 and employing the manufacturing processes described above. The third exemplary electrical fuse 406 comprises a constructive interference portion 77 having a first width W1, a first neck portion N1 abutting the constructive interference portion 77 and having a second width W2, and a second neck portion N2 abutting the constructive interface portion 77, disjoined from the first neck portion N1, and having a third width W3. The properties of the first, second, and third widths (W1, W2, W3) are the same as in the first embodiment.

The fuselink 76 comprises an anode adjoining portion 78 and a cathode adjoining portion 79. The anode adjoining portion 78 has a fourth width W4 and abuts the anode 66 and the first neck portion N1. The cathode adjoining portion 79 has a fifth width W5 and abuts the cathode 86 and the second neck portion N2.

The third exemplary electrical fuse 406 further comprises a pair of substantially parallel constructive interface portion edges 177 located on the constructive interference portion 77 and separated by the first width W1, a pair of substantially parallel anode adjoining portion edges 178 located on the anode adjoining portion 78 and separated by the fourth width W4, and a pair of substantially parallel cathode adjoining portion edges 179 located on the cathode adjoining portion 79 and separated by the fifth width W5.

Preferably, the fourth width W4 and the fifth width W5 are substantially the same as the first width W1, which is substantially the same as the critical dimension. The pair of the substantially parallel constructive interface portion edges 177 may be substantially coincident with extensions of the pair of the substantially parallel anode adjoining portion edges 178 and the pair of the substantially parallel cathode adjoining portion edges 179.

It is explicitly contemplated herein that the fourth width W4 and/or the fifth width W5 may be different from the first width W1. This is achieved by modifying the rectangular fuselink shape 70 in FIG. 7A to increase the width of the anode adjoining shape 68 and/or the width of the cathode adjoining shape 88.

As in the first embodiment, no physical shape other than the anode 66 and cathode 86 is present at the same level as the fuselink 76 within the distance of two times the critical dimension from the fuselink 76. More preferably, no physical shape other than the anode 66 and cathode 86 is present at the same level as the fuselink 76 within the distance of four times the critical dimension from the fuselink.

Preferably, the various sublithographic assist features (90, 92, 94) are rectangular and have the same widths. Some of the various sublithographic assist features (90, 92, 94) may be separated by breaks. For example, one of the at least one sublithographic assist feature 90 may be separated from one of the another at least one sublithographic assist feature 92 by a first break B1. Similarly, one of the at least one sublithographic assist feature 90 may be separated from one of the yet another at least one sublithographic assist feature 94 by a second break B2.

Preferably, the pair of the substantially parallel anode adjoining portion edges 178 and the pair of the substantially parallel cathode adjoining portion edges 179 is parallel to each other and offset by a distance greater than the critical dimension. The pair of the substantially parallel constructive interface portion edges 177 may be at an angle to the pair of the substantially parallel anode adjoining portion edges 178, wherein the angle is in the range from 0 degree to 180 degrees. The angle may be substantially 90 degrees.

The anode 66 and the cathode 88 are on opposite sides of an imaginary line spanning the center of the constructive interference portion 77 in the direction parallel to the pair of the substantially parallel constructive interface portion edges 177.

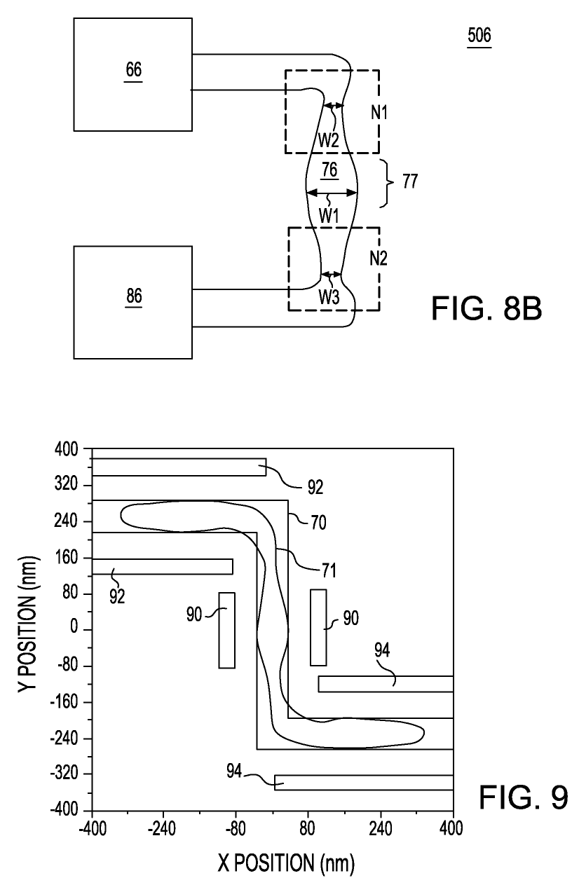

Referring to FIG. 8A, a top-down view of a fourth exemplary photolithographic mask 500 according to a fourth embodiment of the present invention is shown. The fourth exemplary photolithographic mask 500 has similar structural characteristics as the third exemplary photolithographic mask 400 except that the anode shape 60 and the cathode shape 80 are on the same side of an imaginary line drawn in the middle of and parallel to the pair of two substantially parallel edges 170.

Referring to FIG. 8B, a top-down view of a fourth exemplary electrical fuse 506 is shown. The fourth exemplary electrical fuse 506 has similar structural characteristics as the third exemplary electrical fuse 406 except that the anode 66 and the cathode 88 are on the same side of an imaginary line spanning the center of the constructive interference portion 77 in the direction parallel to the pair of the substantially parallel constructive interface portion edges 177.

Referring to FIG. 9, the result of a simulation for a developed fuselink image 71 (as shown in FIG. 3) of a third exemplary photolithography mask 400 according to the third embodiment of the present invention. A scaled layout of the third exemplary photolithographic mask 400, which comprises the fuselink shape 70, at least one SLAF 90, at least another SLAF 92, and at least yet another SLAF 94, is superposed to the fuselink image 71. The simulated fuselink image 71 shows the features of the present invention as described above.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. An electrical fuse comprising:
an anode located on a semiconductor substrate;
a cathode located on said semiconductor substrate and disjoined from said anode; and
a fuselink located on said semiconductor substrate and abutting said anode and said cathode, wherein said fuselink contains a constructive interference portion having a first width, a first neck portion abutting said constructive interference portion and having a second width, and a second neck portion abutting said constructive interface portion, disjoined from said first neck portion, and having a third width, wherein said first width is substantially a critical dimension of a lithography tool, and said second and third widths are sublithographic dimensions of said lithography tool.

2. The electrical fuse of claim 1, wherein said first width is obtained by a constructive interference of a fuselink shape and at least one sublithographic assist feature on a photolithography mask.

3. The electrical fuse of claim 1, wherein said constructive interference portion has substantially the same width between said first neck and said second neck.

4. The electrical fuse of claim 1, wherein said first neck abuts said anode and said second neck abuts said cathode.

5. The electrical fuse of claim 1, wherein said fuselink further comprises:
an anode adjoining portion having a fourth width and abutting said anode and said first neck; and
a cathode adjoining portion having a fifth width and abutting said cathode and said second neck.

6. The electrical fuse of claim 5, further comprising:
a pair of substantially parallel constructive interface portion edges separated by said first width;
a pair of substantially parallel anode adjoining portion edges separated by said fourth width; and
a pair of substantially parallel cathode adjoining portion edges separated by said fifth width.

7. The electrical fuse of claim 6, wherein said pair of said substantially parallel constructive interface portion edges are substantially coincident with said pair of said substantially parallel anode adjoining portion edges and said pair of said substantially parallel cathode adjoining portion edges.

8. The electrical fuse of claim 6, wherein said pair of said substantially parallel anode adjoining portion edges and said pair of said substantially parallel cathode adjoining portion edges are substantially parallel to each other and offset by a distance greater than said critical dimension.

9. The electrical fuse of claim 8, wherein said pair of said substantially parallel constructive interface portion edges are at an angle to said pair of said substantially parallel anode adjoining portion edges, wherein said angle is in the range from 0 degree to 180 degrees.

10. The electrical fuse of claim 8, wherein said angle is substantially 90 degrees.

11. A photolithography mask having a pattern of at least one opaque potion and at least one transparent portion, said pattern comprising:
an anode shape;
a cathode shape disjoined from said anode shape;
a fuselink shape having a pair of two substantially parallel edges and abutting said anode shape and said cathode shape; and
at least one sublithographic assist feature not adjoining said fuselink shape, wherein an image of said photolithography mask contains a constructive interference portion having a first width, a first neck portion abutting said constructive interference portion and having a second width, and a second neck portion abutting said constructive interface portion, disjoined from said first neck portion, and having a third width, and said first width is substantially a critical dimension of a lithography tool, and said second and third widths are sublithographic dimensions of said lithography tool.

12. The photolithography mask of claim 11, wherein said first width is obtained by a constructive interference of said fuselink shape and said at least one sublithographic assist feature on said photolithography mask.

13. The photolithography mask of claim 11, wherein said at least one sublithographic assist feature has a length substantially the same as the length of said constructive interference portion.

14. The photolithography mask of claim 11, wherein said at least one sublithographic assist feature comprises a pair of sublithographic assist features located on each side of said fuselink shape.

15. The photolithography mask of claim 11, wherein no pattern is present between said at least one sublithographic assist feature and said anode shape and between said at least one sublithographic assist feature and said cathode shape.

16. The photolithography mask of claim 11, further comprising:
at least another sublithographic assist feature located between said at least one sublithographic assist feature and said anode; and
at least yet another sublithographic assist feature located between said at least one sublithographic assist feature and said cathode.

17. The photolithography mask of claim 11, wherein said pair of two substantially parallel edges abut said anode shape and said cathode shape.

18. The photolithography mask of claim 11, wherein said fuselink shape further comprises:
an anode adjoining shape having another pair of substantially parallel edges; and
a cathode adjoining shape having yet another pair of substantially parallel edges.

19. The photolithography mask of claim 18, wherein said another pair of substantially parallel edges and said pair of said yet another pair of substantially parallel edges are parallel to each other and offset by a distance greater than said critical dimension.

20. The photolithography mask of claim 19, wherein said pair of two substantially parallel edges are at an angle to said another pair of substantially parallel edges, wherein said angle is in the range from 0 degree to 180 degrees.
